(19) United States
(12) Patent Application Publication
(10) Pub. No.: US 2008/0251891 A1
(43) Pub. Date: Oct. 16, 2008

(54) Semiconductor having passivated sidewalls

(76) Inventors: Yeong-Chang Chou, Irvine, CA (US); Peter S. Nam, Fullerton, CA (US); Chun H. Lin, Torrance, CA (US); Augusto Gutierrez, Redondo Beach, CA (US); Jeffrey Ming-Jer Yang, Cerritos, CA (US); Michael Wojtowicz, Long Beach, CA (US)

Correspondence Address: PATTI, HEWITT & AREZINA LLC, ONE NORTH LASALLE STREET, 44TH FLOOR, CHICAGO, IL, 60602, US

(21) Appl. No.: 11/784,872

(22) Filed: Apr. 10, 2007

(51) Int. Cl. H01L 23/58; H01L 21/00

(52) U.S. Cl. 257/626; 438/465; 257/E21.001; 257/E23.001; 257/E29.001

(57) ABSTRACT

The layers of a semiconductor device have exposed edges. The layers that are susceptible to oxidation are protected from oxidation by coating them with a nitride passivation layer. The nitride passivation layer can be applied using plasma enhanced chemical vapor deposition (PECVD). A method of making a passivated sidewall semiconductor includes the steps of applying a nitride or other protective material over a wafer using PECVD or other appropriate deposition method.

### STATEMENT OF GOVERNMENT RIGHTS

is invention was made with Government support under Contract No. FA8750-06-C-0051, United States Air Force, Air Force Research Laboratory. The government has certain rights in this invention.

### TECHNICAL FIELD

The invention relates generally to semiconductors and methods of making semiconductors. More particularly, this invention relates to antimony based compound semiconductors (ABCS) semiconductors and semiconductors that have or include oxidation-prone materials such as aluminum.

### BACKGROUND

Antimony based compound semiconductors (ABCS) are presently believed to hold great promise for communications devices, communications equipment and other information processing devices and applications that require ultra-low power consumption and light weight. A problem with prior art semiconductors, and in particular, ABCS semiconductors, is that some materials, such as aluminum, are susceptible to oxidation. More particularly, after an ABCS device is formed, the epitaxial layers of the finished device are susceptible to oxidation caused by ambient oxygen as well as processing agents. A semiconductor that is made less susceptible to oxidation would be an improvement over the prior art. Similarly, a method of making a semiconductor device that reduces or eliminates layer oxidation would be an improvement over the prior art.

### SUMMARY

A semiconductor device that provides protection for exposed epitaxial layers and enhance device reliability includes a passivation layer that is applied to an entire semiconductor wafer just prior to dicing the wafer into individual semiconductor devices. In other words, a passivation layer is applied over the sidewalls and wafer substrate. This passivation layer protects exposed edges of the layers of the devices from oxidation.

A method of making a semiconductor device to protect its layers from post-dicing oxidation includes steps of etching or forming a saw lane down to the wafer's substrate; depositing a passivation layer over the sidewalls and substrate; etching away the passivation layer from the substrate where a dicing saw will cut the wafer into individual devices and thereafter, dicing the wafer.

### BRIEF DESCRIPTION OF THE DRAWINGS

FIG. 1A shows a side view of two semiconductor devices formed on a wafer and their respective sidewalls;

FIG. 1B shows the device of FIG. 1A, after the buffer layer is etched;

FIG. 1C shows the device of FIG. 1B, after a nitride passivation layer is applied;

FIG. 1D shows the device of FIG. 1C, after the nitride passivation layer is etched where the saw lane will be located; and

FIG. 1E shows the two separate semiconductor devices formed by dicing.

### DETAILED DESCRIPTION

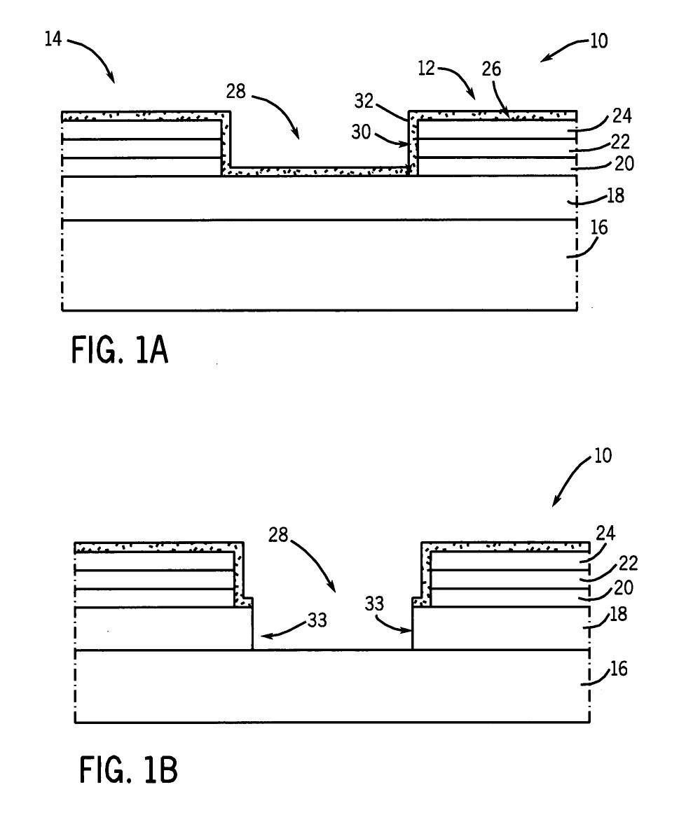

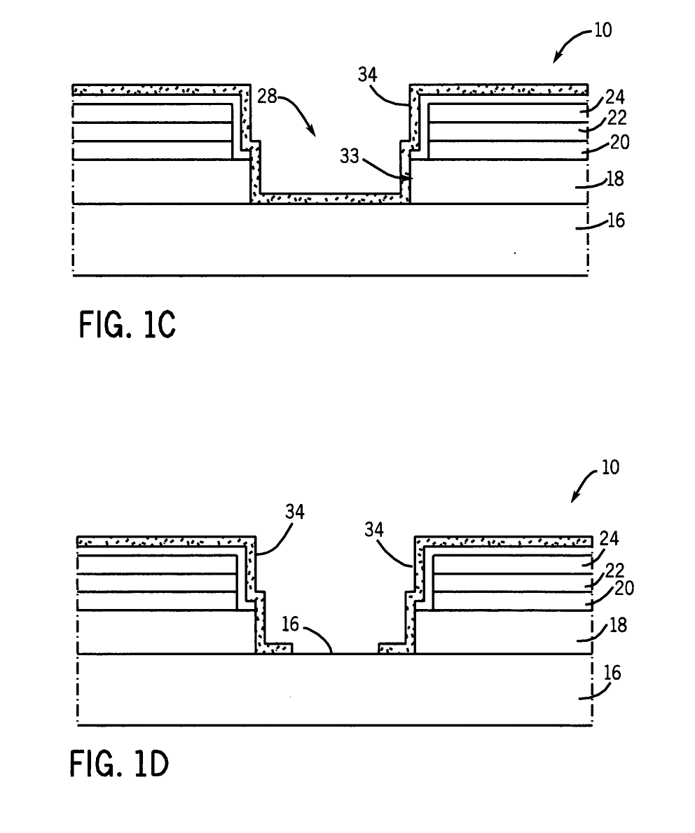

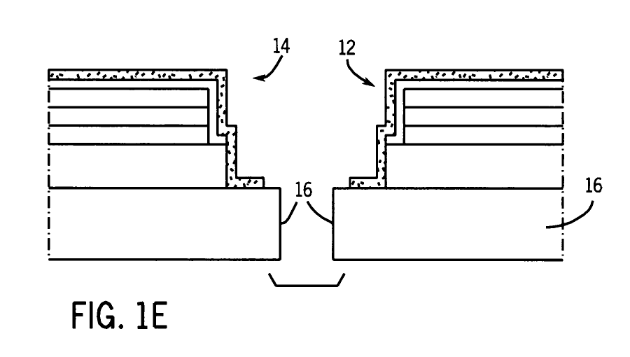

FIG. 1A shows a representation of a side or cross-sectional view of a semiconductor wafer 10 and the cross sectional views of two separate semiconductor devices 12 and 14 formed on the substrate 16 of the same semiconductor wafer 10. As can be seen in this figure, an epitaxial buffer layer 18 is overlaid a silicon or gallium arsenide substrate 16. Several separate epitaxial layers (only three depicted for clarity and simplicity) 20, 22, and 24 are overlaid the buffer layer 18. Using materials and methods known to those of ordinary skill in the art, the layers 20, 22 and 24, amongst others, are used to form active and passive devices and circuit paths of the semiconductor devices 12 and 14. The layers depicted in the figures include at least a first barrier layer 20, a channel layer 22 and a second barrier layer 24.

Each of the layers 20, 22 and 24 have a non-zero thickness. Each layer 20, 22 and 24 therefore has an outwardly exposed lateral edge, one of which is shown in the figures as adjacent to a saw lane 28. (In the figures, only the exposed edge adjacent to saw lane 28 is shown.)

As is known in the art, multiple semiconductor devices 12 and 14, having the same structure are formed together as part of the wafer 10. The saw lane 28 is a trough or trench, along and through which, a dicing saw will cut the semiconductor devices 12 and 14 apart from each other thereby forming two separate semiconductor devices 12 and 14 that were formed together. The saw lane 28 therefore accommodates the dicing saw's kerf.

At the bottom of the saw lane 28 is a first buffer layer 18, which is depicted in FIG. 1B as being removed, preferably by being etched away using an appropriate etching agent. The buffer layer 18 is etched away where a dicing saw 28 will cut the two semiconductor devices 12 and 14 away from each other. Reference numeral 33 identifies the exposed sidewalls or edges of the buffer layer 18.

After the buffer layer 18 is etched away, a protective passivation layer 34 is deposited over the entire surface of the wafer 10, including over the substrate 16, as shown in FIG. 1C. The passivation layer 34 applied over the wafer 10 protects (passivates) the lateral edges (facing sideways or outwardly) of the layers of the devices 12 and 14 from oxidation.

In a preferred embodiment, the passivation layer 34 is a nitride layer, which is deposited onto the wafer 10 using plasma enhanced chemical vapor deposition (PECVD) and which seals the devices 12 and 14 and the edges of the devices 12 and 14 from oxygen. In alternate embodiments, an oxidation layer 32 can be formed of silicon dioxide (SiO₂) and silicon oxygen nitride (SiONₓ) layers. The nitride and the silicon dioxide (SiO₂) and silicon oxygen nitride (SiONₓ) layers can also be deposited using inductively-coupled-plasma (ICP) or electron-cyclotron-resonance (ECR) high density plasma chemical vapor deposition (HDPCVD) techniques.

Antimony based compound semiconductors (ABCS), which of course include the semiconductor devices 12 and 14 shown in FIGS. 1A-1E, are formed using aluminum, which is highly susceptible to oxidation. In order to reliably prevent or reduce edge oxidation as well as layer, it is important that the passivation layer material and its thickness be sufficient to seal the layer and/or its edges. In one embodiment, the nitride passivation layer was 0.2 microns thick. Alternate embodiments include passivation layer thicknesses between about 0.1 and 0.5 microns. In the embodiment shown, the nitride passivation layer 34 is also deposited over the top surface 26 as well as the side walls 30 and 33 in order to further protect the devices 12 and 14 from oxidation.

After the nitride passivation layer is applied over the entire wafer 10, it is etched away from where a dicing saw will cut the devices 12 and 14 apart from each other through the saw lane 28. FIG. 1D shows the device of FIG. 1C, after the nitride passivation layer 34 is etched. The nitride is etched away through the saw lane 28 in order to prevent the nitride from damaging during the dicing process.

After the nitride passivation layer 34 is etched away in the saw lane 28 as shown in FIG. 1D, a dicing saw (not shown) cuts the two semiconductor devices 12 and 14 apart from each other by slicing through the substrate layer 16 as shown in FIG. 1E. By cutting through the substrate 16, two separate semiconductor devices 12 and 14 with sidewall protective passivation layers 34 are formed from the wafer 10.

Antimony based compound semiconductors are comprised of materials that include antimony (Sb), aluminum (Al), arsenic (As), indium (In), gallium, (Ga). Aluminum is particularly susceptible to oxidation. As is known in the art, the oxidation of any layer can seriously degrade a devices performance and its lifespan. A protective layer 34 deposited over exposed edges and surfaces of layers prone to oxidation can therefore greatly improve a semiconductor device's reliability.

Those of ordinary skill in the art will recognize that the semiconductor devices described above and the method of making them described above are only examples and are presented for purposes of illustration. The true scope of the invention is set forth in the appurtenant claims.

What is claimed is:

1. A semiconductor device comprised of:
at least one layer having a thickness and at least one lateral edge that faces outwardly; and
an edge-protective layer formed over the at least one lateral edge, the edge-protective layer being of a material and of a thickness effective to reduce oxidation of the at least one lateral edge.

2. The semiconductor device of claim 1, wherein the edge-protective layer is a nitride layer.

3. The semiconductor device of claim 1, further comprised of an oxidation layer, said oxidation layer being formed of silicon dioxide and silicon oxygen nitride layers.

4. The semiconductor device of claim 3, wherein the silicon dioxide and silicon oxygen nitride layers are deposited using at least one of: an inductively-coupled plasma (ICP), and, an electron-cyclotron-resonance (ECR) high density plasma chemical vapor deposition (HDPCVD).

5. The semiconductor device of claim 1, wherein the at least one layer contains aluminum.

6. The semiconductor device of claim 1, wherein the semiconductor device is an antimony based compound semiconductor (ABCS).

7. The semiconductor device of claim 1, wherein the at least one lateral edge, is adjacent to a saw lane of a semiconductor wafer.

8. The semiconductor device of claim 1, wherein the at least one layer has a plurality of edges, each of which faces outwardly and each of which is covered by an edge-protective layer.

9. The semiconductor device of claim 6, wherein the edge-protective layer is a nitride layer.

10. A semiconductor device comprised of:
a plurality of layers, each layer having a thickness and at least one lateral edge that faces outwardly, the at least one lateral edge of the plurality of layers forming a sidewall of the semiconductor device; and
a protective layer formed over the sidewall, the protective layer being effective to reduce oxidation of at least one edge of at least one layer of the plurality of layers.

11. The semiconductor device of claim 10, wherein the protective layer is a nitride layer.

12. The semiconductor device of claim 10 further including an oxidation layer formed of silicon dioxide and silicon oxygen nitride layers.

13. The semiconductor device of claim 12, wherein the silicon dioxide and silicon oxygen nitride layers are deposited using at least one of: an inductively-coupled plasma (ICP), and an electron-cyclotron-resonance (ECR) high density plasma chemical vapor deposition (HDPCVD).

14. The semiconductor device of claim 10, wherein at least one of the plurality of layers contains aluminum.

15. The semiconductor device of claim 10, wherein the semiconductor device is an antimony based compound semiconductor.

16. The semiconductor device of claim 10, wherein the sidewall is adjacent to a saw lane of a semiconductor wafer.

17. The semiconductor device of claim 11, wherein the nitride layer is applied using plasma enhanced chemical vapor deposition.

18. A semiconductor device comprised of:
a plurality of layers, at least one of which contains aluminum, each layer having a thickness and at least one lateral edge that faces outwardly, the at least one lateral edge of the plurality of layers forming a sidewall of the semiconductor device; and
a nitride layer formed over the sidewall, the nitride being effective to reduce oxidation of at least one edge of at least one layer of the plurality of layers.

19. The semiconductor device of claim 18, wherein one of the plurality of layers is a top layer having a top surface; and wherein the nitride layer is also formed over the top surface.

20. The semiconductor device of claim 18, further comprised of an oxidation layer comprised of silicon dioxide and silicon oxygen nitride layers, and which are deposited using at least one of: an inductively-coupled plasma (ICP), and, an electron-cyclotron-resonance (ECR) high density plasma chemical vapor deposition (HDPCVD).

21. The semiconductor device of claim 18, wherein the semiconductor device is an antimony based compound semiconductor.

22. The semiconductor device of claim 18, wherein the sidewall is adjacent to a saw lane of a semiconductor wafer.

23. The semiconductor device of claim 18, wherein the nitride layer is applied using plasma enhanced chemical vapor deposition.

24. A semiconductor wafer comprised of:
a plurality of multi-layer semiconductor devices, at least one of the multi-layer semiconductor devices having a sidewall that is adjacent to a saw lane;
a nitride layer formed over said sidewall, the nitride layer being effective to reduce oxidation of a material within the semiconductor device.

25. The semiconductor wafer of claim 24, wherein said nitride layer is also formed over a top surface of the at least one multi-layer semiconductor device.

26. The semiconductor wafer of claim 24, further comprised of an oxidation layer comprised of silicon dioxide and silicon oxygen nitride layers, which are deposited using at least one of: an inductively-coupled plasma (ICP), and, an electron-cyclotron-resonance (ECR) high density plasma chemical vapor deposition (HDPCVD).

27. The semiconductor device of claim 24, wherein the semiconductor device is an antimony based compound semiconductor.

28. A method of making a semiconductor comprising the steps of:
sequentially depositing layers of materials onto a substrate to form a wafer that is comprised of a plurality of separate semiconductor devices, at least one of the layers of the semiconductor device containing aluminum;
etching the semiconductor wafer to form a sidewall adjacent to a saw lane where the semiconductor wafer is cut to separate a semiconductor device from the wafer;
applying a nitride passivation layer over the sidewall;
cutting the wafer along the saw lane to sever the semiconductor device from the wafer;
wherein the semiconductor device severed from the wafer has at least one sidewall that is substantially covered by the nitride layer.

29. The method of claim 28 wherein the wafer is comprised of antimony based compound semiconductors.

30. The method of claim 28 further comprised of the step of: applying a nitride layer on a top surface of the layers of materials that are deposited onto the substrate.

31. The method of claim 28, further comprised of: depositing an oxidation layer comprised of silicon dioxide and silicon oxygen nitride layers, the step of depositing an oxidation layer being performed using at least one of: an inductively-coupled plasma (ICP), and, an electron-cyclotron-resonance (ECR) high density plasma chemical vapor deposition (HDPCVD).
